(19) United States
(12) Patent Application Publication
(10) Pub. No.: US 2014/0211566 A1
(43) Pub. Date: Jul. 31, 2014

(54) SEMICONDUCTOR MEMORY DEVICE

(71) Applicant: KABUSHIKI KAISHA TOSHIBA, Tokyo (JP)

(72) Inventor: Fumihiro KONO, Kanagawa (JP)

(73) Assignee: KABUSHIKI KAISHA TOSHIBA, Tokyo (JP)

(21) Appl. No.: 14/015,994

(22) Filed: Aug. 30, 2013

(30) Foreign Application Priority Data
Jan. 31, 2013 (JP) 2013-017765

(51) Int. Cl. G11C 16/04

(52) U.S. Cl. CPC G11C 16/04
USPC 365/185.05

(57) ABSTRACT

According to one embodiment, a semiconductor memory device includes a first sense amplifier that is located in a first region and amplifies signals from a memory cell in the first region. A second sense amplifier is located in a second region and amplifies signals from a memory cell in the second region. A bus is connected to the first and second sense amplifiers and passes through the first and second regions. A first latch is located in the second region and is connected to the bus. A second latch is located in the second region and is connected to the bus.

### CROSS-REFERENCE TO RELATED APPLICATION

This application is based upon and claims the benefit of priority from Japanese Patent Application No. 2013-017765, filed Jan. 31, 2013, the entire contents of which are incorporated herein by reference.

### FIELD

Embodiments described herein relate generally to a semiconductor memory device.

### BACKGROUND

Three dimensional NAND-type flash memories which are manufactured using a BiCS manufacturing technology are known in the art.

### DESCRIPTION OF THE DRAWINGS

FIG. 1 is a diagram that conceptually shows a layout of one part of a semiconductor memory device.

FIG. 2 is a block diagram of a semiconductor memory device according to a first embodiment.

FIG. 3 is a perspective view of a part of a memory cell array according to the first embodiment.

FIG. 4 is a cross-sectional diagram of the part of the memory cell array according to the first embodiment.

FIG. 5 is a cross-sectional diagram of a memory cell transistor according to the first embodiment.

FIG. 6 is a diagram that conceptually shows a layout of one part of the semiconductor memory device according to the first embodiment.

FIG. 7 is a diagram that shows an example of a comparative layout.

FIG. 8 is a diagram that shows an example of a comparative layout.

FIG. 9 is a diagram that conceptually shows a layout of one part of a semiconductor memory device according to a second embodiment.

FIG. 10 is a diagram that shows an example of data transfer according to the second embodiment.

FIG. 11 is a diagram that shows another example of the data transfer according to the second embodiment.

### DETAILED DESCRIPTION

According to the present disclosure, there is provided a semiconductor memory device that can achieve high-speed performance with a small footprint.

In general, according to one embodiment, a semiconductor memory device includes a first sense amplifier that is located in a first region and amplifies signals from a memory cell in the first region. A second sense amplifier is located in a second region and amplifies signals from a memory cell in the second region. A bus connected to the first and second sense amplifiers passes through the first and second regions. A first latch is located in the second region and is connected to the bus. A second latch is located in the second region and is connected to the bus.

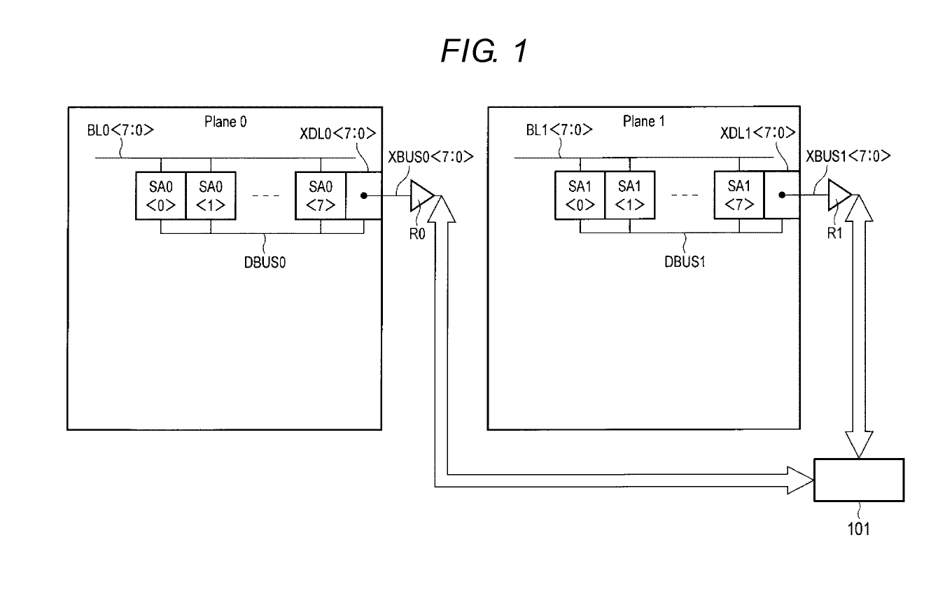

The present inventors, in the process of developing an embodiment, obtained the following knowledge. With the BiCS style of memory, unlike conventional non-three-dimensionally structured NAND-type flash memory, a circuit can be placed below a memory cell array. Examples of such a circuit are, for example, peripheral circuits such as sense amplifiers, and the like. FIG. 1 shows a layout of a part of the BiCS memory, without expressing mutual positional relationships of each element (components, wirings, circuits, and the like) in the vertical direction (in the direction that intersects with a substrate).

As shown in FIG. 1, bit lines BL0<7:0> that are connected to the memory cell is provided. The expression <α:β> means β-th through α-th bit lines, for a total of <α>-<β>+1 bit lines. Eight bit lines BL0<7:0> are shown as examples, and in the following elements. The bit lines BL0<7:0> are each connected to each end of sense amplifier units SA0<0> to SA0<7>. Each of the other ends of the sense amplifier units SA0<0> to SA0<7> is connected to each of data latches (henceforth, simply latches) XDL0<7:0> through a common data bus DBUS0. Selected ones of the sense amplifier units SA0<0> to SA0<7> connect to a corresponding one of the latches XDL0<0> to XDL0<7> via the data BUS0. The latches XDL0<7:0> are located on one edge (for example, the right side) of a plane 0. Latches XDL0<7:0> are connected to a pad on a data input-output circuit 101 through XBUS0<7:0> which includes (a bus, a circuit, and the like). The data input-output circuit 101 is located close to one of two planes (for example, a plane 1) and far from the other plane (for example, the plane 0).

The plane 1 has the same elements and connections as the plane 0. That is, the bit lines BL0<7:0>, the sense amplifier units SA0<0> to SA0<7>, the data bus DBUS0, the latches XDL0<7:0>, and the bus XBUS0<7:0> of the plane 0 each have corresponding structures in plane 1, i.e., bit lines BL1<7:0>, sense amplifier units SA1<0> to SA1<7>, a data bus DBUS1, XDL1<7:0>, and bus XBUS1<7:0> and latches XDL1<7:0> in the plane 1. Data that are output to a location external to the memory are retained in the latches XDL0<7:0> and the latches XDL1<7:0> and are output from there at specified times.

In a memory that has multiple planes such as the example shown in FIG. 1, the timing between the multiple planes is also controlled. This control includes the timings for the transfer of output data from each of the planes 0 and 1. However, the data transfer from the latches XDL0<7:0> to the input-output circuit 101 takes longer than the time for the data transfer from the latches XDL1<7:0> to the input-output circuit 101, because the latches in plane 0 are further from the input output circuit than are the latches in plane 1. As a result, a different amount of time is necessary for the data that are read out from the memory cell to arrive at the data input-output circuit 101 from each different plane of the multi-plane memory, and timing control across multiple planes is difficult. This fact reduces the operational margin of the memory and, by extension, can hinder high-speed operation of the memory.

Below, an embodiment configured based on this knowledge is described with reference to the figures. Meanwhile, in the descriptions, compositional elements that possess nearly the same functions and structures will be given the same symbols, and redundant descriptions will be given only when necessary. Also, the figures are schematic. For simplification, there are cases wherein an element shown in one figure is omitted in another related figure.

Furthermore, each of the embodiments exemplifies the devices and methods to realize the technical ideas of this embodiment, and the technical embodiment of this embodiment is not limited to the materials, form, structure, placement, and the like of the components described herein. The technical idea of the embodiment can be variously changed within the scope of the claims.

### First Embodiment

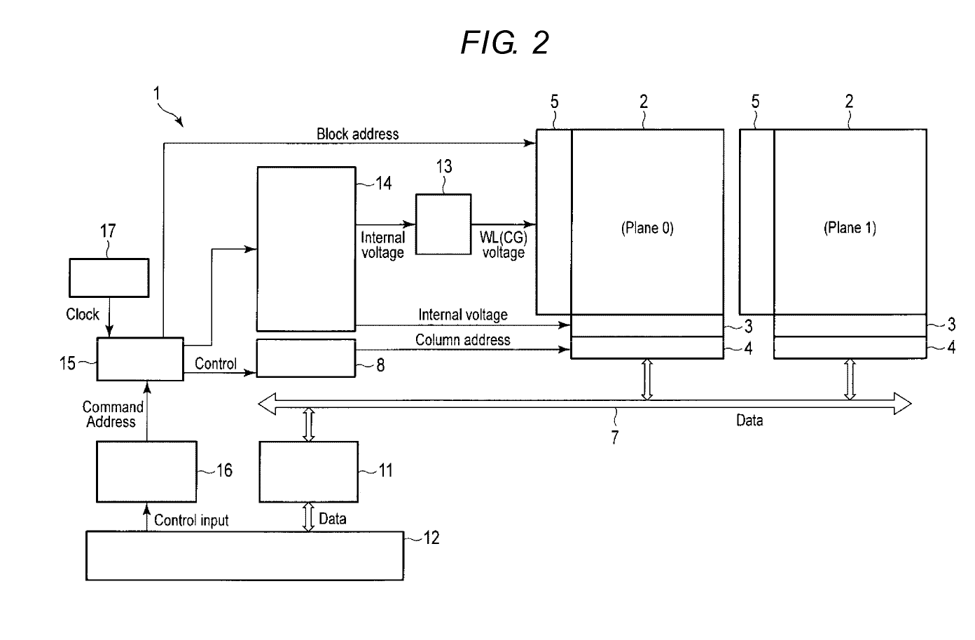

FIG. 2 is a block diagram of a semiconductor memory device according to a first embodiment. Each functional block can be actualized as either hardware or computer software or a combination of the two. For this reason, to clarify that each functional block can be actualized in both forms, the explanation is made from the point of view of those functions as a whole. Whether these functions are executed as hardware or software depends on the design constraints that are imposed on the specific embodiment or the entire system. A person skilled in the art can realize these functions with various methods for each specific embodiment, but any method of realization is included in the scope of the embodiments. Also, each functional block does not need to be differentiated as in the specific examples provided herein. For example, part of the function can be executed by a functional block that is different from the functional block that is exemplified in the descriptions. Furthermore, a functional block in the examples can be subdivided into smaller functional sub-blocks. An embodiment is not limited by what functional block that the embodiment describes.

As shown in FIG. 2, a semiconductor memory device 1 includes elements such as a memory cell array 2, a sense amplifier 3, a page buffer 4, a row decoder 5, a data bus 7, a column decoder 8, a serial access controller 11, an I/O interface 12, a CG driver 13, a voltage generator 14, a sequencer 15, a command user interface 16, an oscillator 17, and the like. The semiconductor memory device 1, for example, corresponds to one semiconductor chip and is controlled by, for example, an external controller.

The semiconductor memory device 1 includes multiple memory cell arrays 2. FIG. 2 exemplifies two memory cell arrays 2, but the semiconductor memory device 1 can include three or more memory cell arrays 2. Each memory cell array 2 can also be called a plane. The two planes shown are called a plane 0 and a plane 1. Each memory cell array 2 includes multiple blocks (memory blocks). Each block possesses multiple strings. A string includes multiple memory cell transistors that are serially connected and two select gate transistors on either end thereof. Multiple such strings are connected to a single bit line. Some of the multiple memory cell transistors share a word line. A memory space of the multiple memory cell transistors that share the word line across the multiple strings that are aligned along the direction of the bit lines in each block are configured as one or more pages. Data are read or written per page and are erased per block. The memory cell array 2 has a three-dimensional structure based on a so-called BiCS technology, which will be explained in detail later. The semiconductor memory device 1 can retain data of greater than or equal to 2 bits per one memory cell.

A combination of a sense amplifier 3, a page buffer 4, and a row decoder 5 are provided for each memory cell array 2. Each sense amplifier 3 includes multiple sense amplifier units that are each connected to multiple bit lines and the sense amplifier senses and amplifies the electric potential of the signal on the bit lines. Each page buffer 4 receives a column address and, based on the column address, temporarily retains data from a specific memory cell transistor during readout, then outputs the stored data to the data bus 7. Also, each page buffer 4, based on the column address, receives external data from the outside of the semiconductor memory device 1 during the write operation via the data bus 7 and temporarily retains the received data. The column address is supplied by the column decoder 8.

The data bus 7 is connected to the serial access controller 11. The serial access controller 11 is connected with the I/O interface 12. The I/O interface 12 includes multiple signal terminals (pads) and acts as the interface between the semiconductor memory device 1 and an external device and sends and receives data to and from the external device. The serial access controller 11 executes control, including the conversion of parallel signals on the data bus 7 and serial signals from the I/O interface 12.

Each row decoder 5 receives a block address and a string address and, based on the received signal, selects the block and string. Specifically, each row decoder 5 is connected to the CG driver 13 and connects multiple outputs of the CG driver 13 with a string that is selected from selected blocks. The CG driver 13 receives a voltage from the voltage generator 14 and generates a voltage necessary for the various operations (read, write, erase, and the like) of the semiconductor memory device 1. The voltage that is output from the CG driver 13 is applied to a gate electrode of the word lines and the select gate transistors. The voltage generator 14 also provides a voltage necessary for the operation of the sense amplifier 3.

The sequencer 15 receives signals, such as command, and address, from the command user interface 16 and operates based on clocks from the oscillator 17. The sequencer 15, based on the signals received, controls various elements (functional blocks) in the semiconductor memory device 1. For example, the sequencer 15 controls the column decoder 8 and the voltage generator 14 based on the received signals, such as the command and the address. Also, the sequencer 15 outputs the block address based on the received signals such as the command and the address. The command user interface 16 receives control signals via the I/O interface 12. The command user interface 16 decodes the received control signals and obtains the command, the address, and the like.

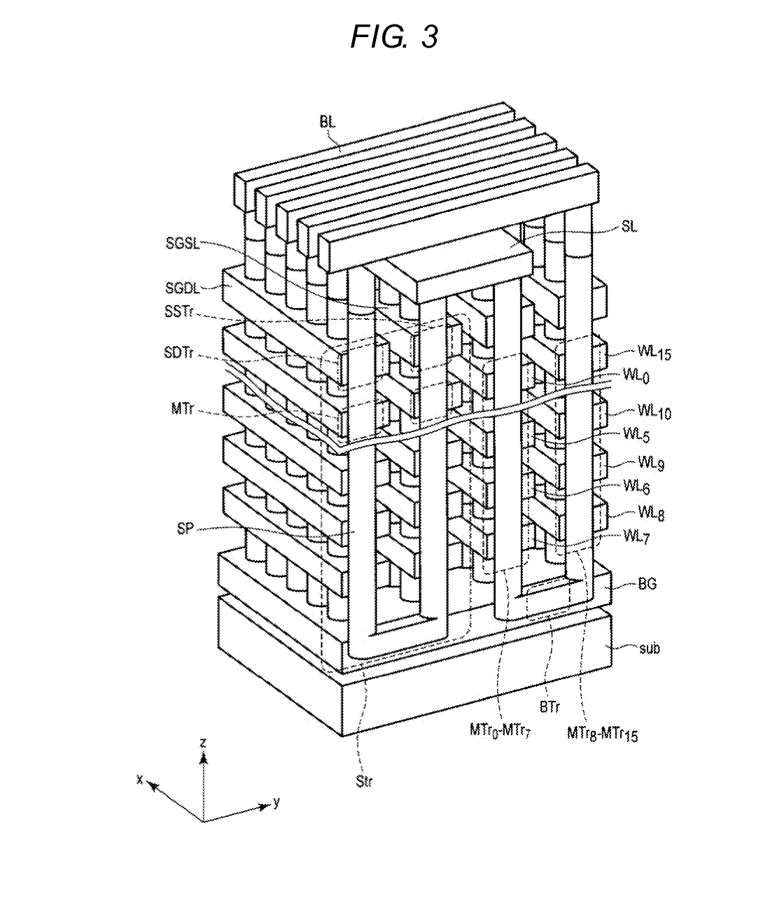

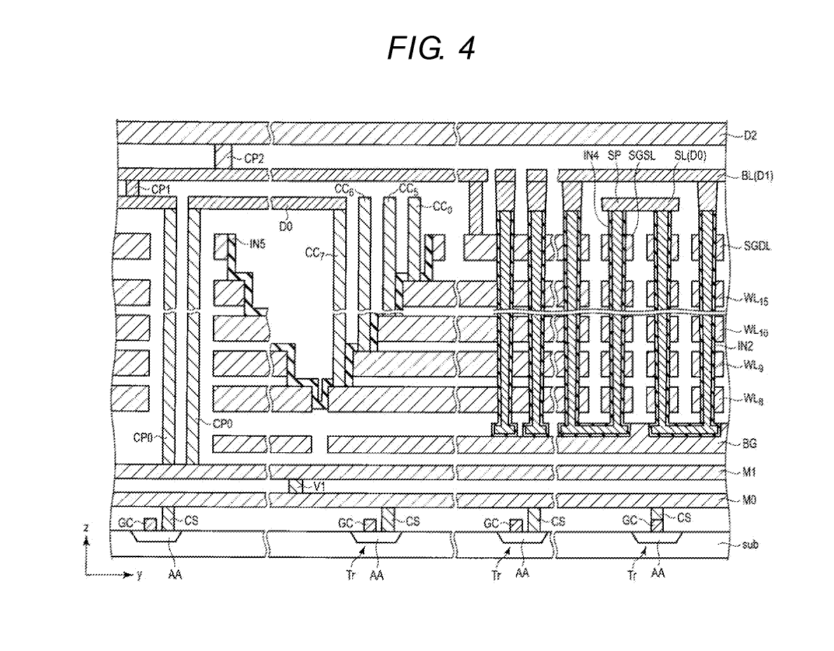

Each memory cell array 2 possesses a structure shown, for example, in FIGS. 3 and 4. FIG. 3 is a perspective view of part of the memory cell array according to the first embodiment. FIG. 4 is a cross-sectional diagram of part of the memory cell array according to the first embodiment. FIG. 3 shows two strings. FIG. 4 shows a section of the array along a Y-Z surface.

As shown in FIGS. 3 and 4, an active region AA (FIG. 4 only) and a transistor Tr are formed above a substrate sub. The active region AA and the transistor Tr configure one part of the peripheral circuit (for example, the sense amplifier 3). The transistor Tr is formed in the active region AA on the surface of the substrate sub and it includes a source/drain region (not shown), a gate electrode GC (FIG. 4), and the like for example. A wire layer M0 (FIG. 4) is formed above the substrate sub. The wire layer M0 is connected to the gate electrode GC and the active region AA (source/drain region) by a conductive plug CS. A wire layer M1 extends above the wire layer M0. The wire layer M1 is connected to the wire layer M0 via a plug V1.

A back gate layer BG made of conductive materials is formed above the wire layer M1. The back gate layer BG extends along the X-Y plane of the figures. Also, multiple U shaped strings Str (as shown within dashed outline labeled Str in FIG. 3) are formed above the substrate sub. A single block includes the multiple strings Str.

As seen in FIG. 3, one string Str includes n memory cell transistors MTr, where n is a whole number. FIGS. 3 and 4 show examples wherein one string includes 16 cell transistors MTr₀ to MTr₁₅. In the present specification, when reference codes with a number at the end (for example, cell transistors MTr₀ to MTr₁₅) do not need to be mutually differentiated, they are written with the last number in the reference code omitted. The cell transistors MTr₇ and MTr₈ are connected via aback gate transistor BTr in back gate layer BG. The first ends of the source side select gate transistor SSTr and a drain side select gate transistor SDTr are each connected to the cell transistors MTr₀ and MTr₁₅. Each second end of the transistor SSTr and the transistor SDTr are connected to a source line SL and a bit line BL. The source line SL and the bit line BL each extend above each transistor SSTr and SDTr. The source line SL and the bit line BL are each formed in a wire layer D0 and a wire layer D1 above the wire layer D0.

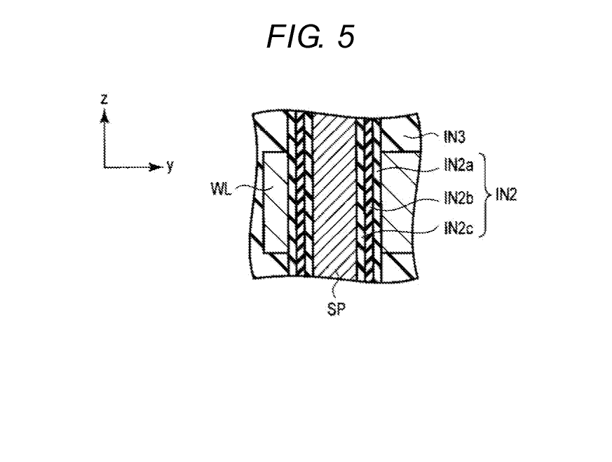

The cell transistors MTrₒ to MTr₁₅ are configured to include a semiconductor cylinder SP and an insulating film IN2 (shown in FIG. 5) on the surface of the semiconductor cylinder SP. The semiconductor cylinder SP above the back gate layer BG is made from, for example, silicon. Two adjacent semiconductor cylinders SP that make up one string Str are connected by a pipe layer that is made of conductive materials in the back gate BG layer. The pipe layer comprises the back gate transistor BTr. The insulating film IN2, as shown in FIG. 5, includes a tunnel insulating film IN2c on the semiconductor cylinder SP, an electric charge trap layer IN2b on the insulating film IN2c, and a block insulating film IN2a on the electric charge trap layer IN2b. The electric charge trap layer IN2b is made from insulating materials.

As shown in FIGS. 3 and 4, the cell transistors MTrₒ to MTr₁₅ each include word lines WL₀ to WL₁₅ that further extend along an x-axis. The word lines WL₀ to WL₁₅ are selectively connected to corresponding CG lines CG (CG lines CG₀ to CG₁₅) by the row decoder 5. The CG line CG is not shown in FIGS. 3 and 4. The cell transistor MTr stores data that are set based on the number of carriers in the electric charge trap layer IN2b in a nonvolatile manner.

A gate electrode (gate) of each cell transistor MTr₀ of the multiple strings Str that are aligned along the x-axis in each block is connected to the word line WL₀. Similarly, each gate of each cell transistor MTr_{X} of the multiple strings Str that are aligned along the x-axis in each block is connected to a word line WL_{X}, where X is 0 or a natural number less than or equal to n. The world line WL₀ is further shared by all of the strings Str in one block. The word lines WL₁ to WL₇ are also similarly shared. The memory space of a set of multiple cell transistors MTr that extend along the x-axis in each block, and are connected to the same word line WL, make up one or multiple pages. One page has, for example, a size of 8 Kbytes. As shown in FIG. 4, the word lines WL₀ to WL₁₅ terminate in a staircase pattern at the ends. That is, some word lines WL are longer than the word lines below and shorter than the word lines above, such that the upper surfaces thereof are exposed from above adjacent to their ends. The word lines WL₀ to WL₁₅ are connected to contact plugs CC₀ to CC₁₅ at the exposed surfaces at each of their end parts. The contact CC is connected to the wire layer M1 via the wire layer D0 and a contact plug CP0. Of the surfaces of the word lines WL₀ to WL₁₅ with the ends exposed, the region where the contact plug CC is not formed is covered by an insulating film IN5.

The select gate transistors SSTr and SDTr include the semiconductor cylinder SP and a gate insulating film (not shown) of the semiconductor cylinder SP and of the surface of the semiconductor cylinder SP, and further includes respectively a gate (a select gate line) SGSL and a gate SGDL.

The gates of each source-side select gate transistor SSTr, of the multiple strings Str that are aligned along the x-axis in each block, are commonly connected to the source side select gate line SGSL. The select gate line SGSL extends along the x-axis. The select gate line SGSL is selectively connected to an SGS line SGS (not shown) by the row decoder 5. First ends of each transistor SSTr of the two adjacent strings Str are connected to the same source line SL. The source lines SL in one block are mutually connected.

The gates of each drain-side select gate transistor SDTr of the multiple strings Str that are aligned along the x-axis in each block MB are commonly connected to the drain side select gate line SGDL. The select gate line SGDL extends along the x-axis. First ends of each transistor SDTr of all strings Str that are aligned along a y-axis and in a single block are connected to the same bit line BL.

The multiple strings Str that are aligned along the x-axis in each block (connected to different bit lines BL) share the selector gate lines SGSL and SGDL and the word lines WL₀ to WL₁₅. The multiple strings Str that are aligned along the x-axis and share the selected gate lines SGSL, SGDL, and the word lines WL₀ to WL₁₅ form a string group. The multiple cell transistors MTr that belong to the same string and are connected to the same word line correspond to a set of transistors that configure one or multiple pages.

In the peripheral circuit region outside of the word line WL, there are also formed the transistor Tr, the wire layers M0 and M1, the plugs CS and V1, and the like, which form a part of the peripheral circuit (for example, the row decoder 5, and the like). The wire layer M1 is electrically connected to an upper-most wire layer D2 via the plug CP0, the wire layer D0, a plug CP1, the wire layer D1, and a plug CP2. Parts of the memory not shown in FIGS. 3 and 4 are embedded by interlayer dielectric films (not shown).

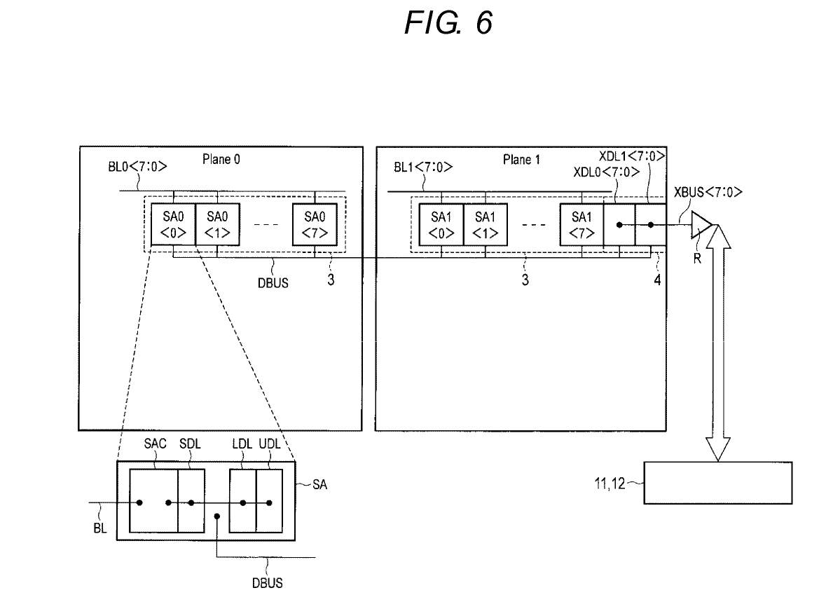

FIG. 6 shows a layout of one part of the semiconductor memory device according to the first embodiment without expressing the mutual positional relationships of each element (the components, the wirings, the circuits, and the like) in the direction along a z-axis. FIG. 6, in the plane 0, shows eight bit lines BL0<7:0> as an example. The bit lines BL0<7:0> are connected to a string in the plane 0.

The bit lines BL0<7:0> are each connected to a side of the sense amplifier units SA0<7> to SA0<0>. The sense amplifier units SA0<0> to SA0<7> are a part of the sense amplifier 3 for the plane 0 and are positioned in the region for the plane 0 (for example, therebelow, along the z-axis of the memory cell array). Each other end of the sense amplifier units SA0<0> to SA0<7> is connected to a common data bus DBUS via a switch (not shown). The data bus DBUS is formed, for example, in the wire layer M1. The data bus DBUS spans from the region in the plane 0 to the region in the plane 1. The data bus DBUS is an element that reaches across the boundary of the sense amplifier 3 and the page buffer 4 in FIG. 1.

Of the sense amplifier units SA0<0> to SA0<7>, one that is selected by the switch is connected to the data bus DBUS. Each of the sense amplifier units SA0<0> to SA0<7> includes, for example, a set of sense amplifier circuits SA and latches SDL, LDL, and UDL. A sense amplifier circuit SAC senses and amplifies signals from the corresponding memory cell on the corresponding bit line. The latches SDL, LDL, and UDL temporarily retain data. The sense amplifier SA and the latches SDL, LDL, and UDL are formed, for example, from the transistor Tr, the wire layers M0 and M1, the plugs CS and V1, and the like.

FIG. 6, with respect to the plane 1, shows eight bit lines BL0<7:0> as an example. The elements show the number of pieces based on the example of the eight bit lines. Bit lines BL1<7:0> are connected with strings in the plane 1.

The bit lines BL1<7:0> are each connected to one side of sense amplifier units SA1<7> to SA1<0>. The sense amplifier units SA1<0> to SA1<7> are a part of the sense amplifier 3 for the plane 1 and are positioned in the region for the plane 1 (for example, therebelow, along the z-axis of the memory cell array). Each other end of the sense amplifier units SA1<0> to SA1<7> is connected to the common data bus DBUS via a switch (not shown). Of the sense amplifier units SA1<0> to SA1<7>, one that is selected by the switch is connected to the data bus DBUS. Each of the sense amplifier units SA1<0> to SA1<7> includes, for example, a set of the sense amplifier circuits SAC and the latches SDL, LDL, and UDL as is also present with respect to plane 0.

The data bus DBUS is also connected to latches XDL0<0> to XDL0<7> (XDL0<7:0>) via the switches of each (not shown). The latches XDL0<0> to XDL0<7> configure one part of the page buffer 4 for the plane 0. The latches XDL0<0> to XDL0<7> each retain data for the sense amplifier units SA0<0> to SA0<7> and are formed from, for example, the transistor Tr, the wire layers M0 and M1, the plugs CS and V1, and the like. One of the latches selected from XDL0<0> to XDL0<7> by the switch is connected to corresponding one of the sense amplifier units SA0<0> to SA0<7> via the data bus DBUS. The selection for this connection is controlled by, for example, the sequencer 15 or the column decoder 8.

The data bus DBUS is also connected to latches XDL1<0>- to XDL1<7> (XDL1<7:0>) via the switches of each (not shown). The latches XDL1<0> to XDL1<7> configure one part of the page buffer 4 for the plane 1. Each of the latches XDL1<0> to XDL1<7> retains data for the sense amplifier units SA1<0> to SA1<7>. One of the latches selected from XDL1<0> to XDL1<7> by the switch is connected to corresponding one of the sense amplifier units SA1<0> to SA1<7> via the data bus DBUS. The selection for this connection is controlled by, for example, the sequencer 15 or the column decoder 8.

The latches XDL0<7:0> and the latches XDL1<7:0> are positioned, for example, in the plane 1. The latches XDL0<7:0> and XDL1<7:0> are, for example, adjacent, and are positioned on the plane 1 on the opposite edge thereof from the plane 0.

The latches XDL0<7> to XDL0<0> are each connected to data buses XBUS<7> to XBUS<0> (XBUS<7:0>) via the switches of each. The selection for this connection is controlled by, for example, the sequencer 15 and the column decoder 8. The latches XDL1<7> to XDL1<0> are also each connected to the data buses XBUS <7> to XBUS <0> via the switches of each. The selection for this connection is controlled by, for example, the sequencer 15 or the column decoder 8. The data buses XBUS<0> to XBUS<7> are elements between the page buffer 4 and the data bus 7 for the planes 0 and 1 in FIG. 2 and are formed, for example, in the wire D2. The data buses XBUS<7:0> are connected to the selected one of the latches XDL0<7:0> and the latches XDL1<7:0>. The selection for this connection is controlled by, for example, the sequencer 15 or the column decoder 8.

The data buses XBUS<7:0> are connected with a receiver circuit R. The receiver circuit R is one element for the data bus 7 of FIG. 2. Signals on the data buses XBUS <7:0> appear on a pad in the I/O interface 12 via the data bus 7 in FIG. 2 and the serial access controller 11.

Until now, an example with two planes is described. However, the first embodiment can be applied to an example with three or more planes. That is, the data bus DBUS passes through all of the planes that of the present embodiment and it is configured to be connectable to the sense amplifier units of all of the planes. Also, the data bus is configured to be connectable to the latches XDL for all of these planes. The latches XDL for each plane are collected in a certain region in each plane. These planes share the data bus XBUS. According to the semiconductor memory device of the first embodiment, these planes share the data bus DBUS, the latches XDL for each of the planes that are connected to the data bus DBUS are collected in one location in one plane, and the data bus XBUS is also shared by multiple planes. Since the latch group XDL for each plane is collected in one location, the distance between the latches for each plane XDL and the I/O interface 12 is almost identical. For this reason, per each plane, there is not a need to conduct control that takes into account the variability in the data transfer speed from the latch XDL to the I/O interface 12 for each plane. This heightens the operational margin of the semiconductor memory device 1 and can contribute to the high-speed operation of the semiconductor memory device 1.

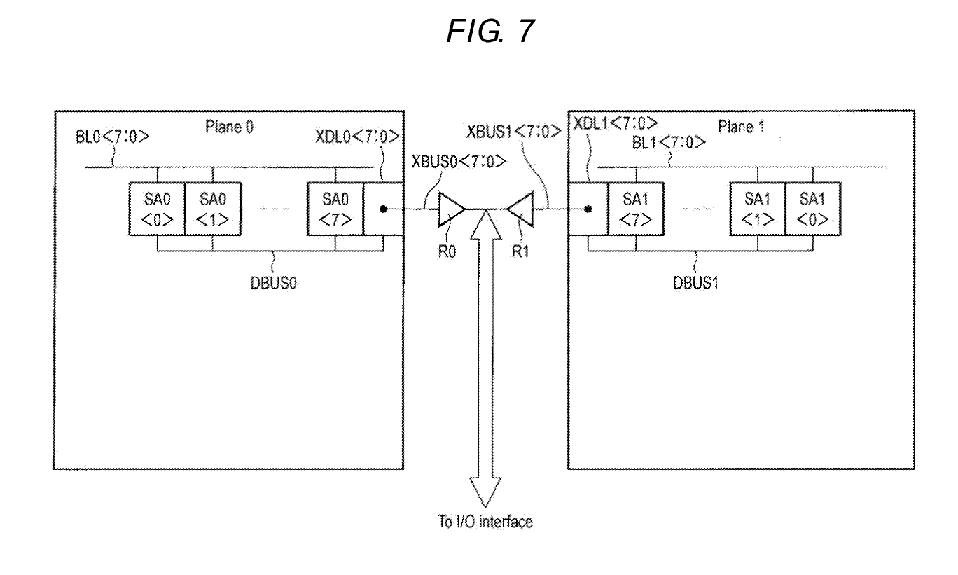

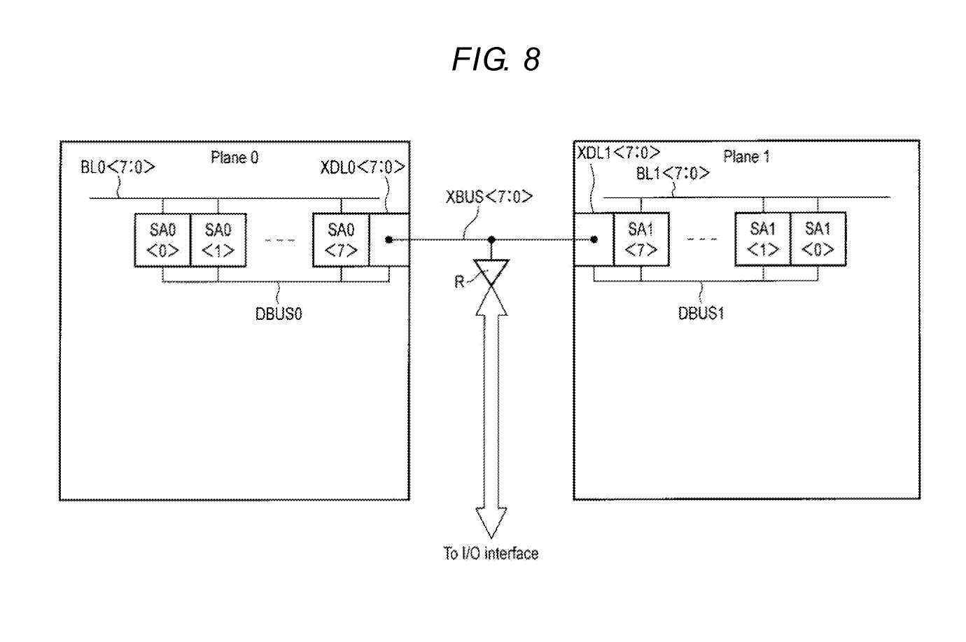

To match the distance between the latch XDL for each plane and the I/O interface 12, a layout that differs from the first embodiment is conceivable. FIGS. 7 and 8 show two such layouts. As shown in FIGS. 7 and 8, the planes 0 and 1 are configured to be axisymmetric, based on the configuration of FIG. 1. That is, the latches XDL0<7:0> are positioned on the plane 1 side, and the latches XDL1<7:0> are positioned on the plane 0 side.

In FIG. 8, the latches XDL0<7:0> and XDL1<7:0> are connected to the data buses XBUS<7:0>. The common data buses XBUS<7:0> extend between the planes 0 and 1 and are connected to the receiver R between the planes. With this layout, the data transfer speed from the latches XDL0<7:0> and XDL1<7:0> to the I/O interface 12 can also be matched.

On the other hand, in FIG. 7, the data buses XBUS0<7:0> and the data buses XBUS1<7:0> extend between the planes 0 and 1 and are each connected to receivers R0 and R1 between the planes. With this layout, the data transfer speed from the latches XDL0<7:0> and XDL1<7:0> to the I/O interface 12 can also be matched. Additionally, since the data buses XBUS<7:0> do not span to the plane 0 and the plane 1, the degree of freedom of the wiring is greater than in the layout in FIG. 7.

Unlike the layouts in FIGS. 7 and 8, according to the first embodiment, the data buses XBUS will not mutually span between the planes, and there is no need to place a receiver circuit mutually between the planes. Instead, in the first embodiment, the receiver circuit R can be placed on the outside of the array of the planes, which is easier than installing the receiver mutually between the planes. Thus, according to the first embodiment, the data transfer speed from the latch XDL for each plane to the I/O interface 12 can be matched without lowering the degree of freedom for the wiring and the placement of components.

### Second Embodiment

A second embodiment is an application of the first embodiment and further includes a temporary latch.

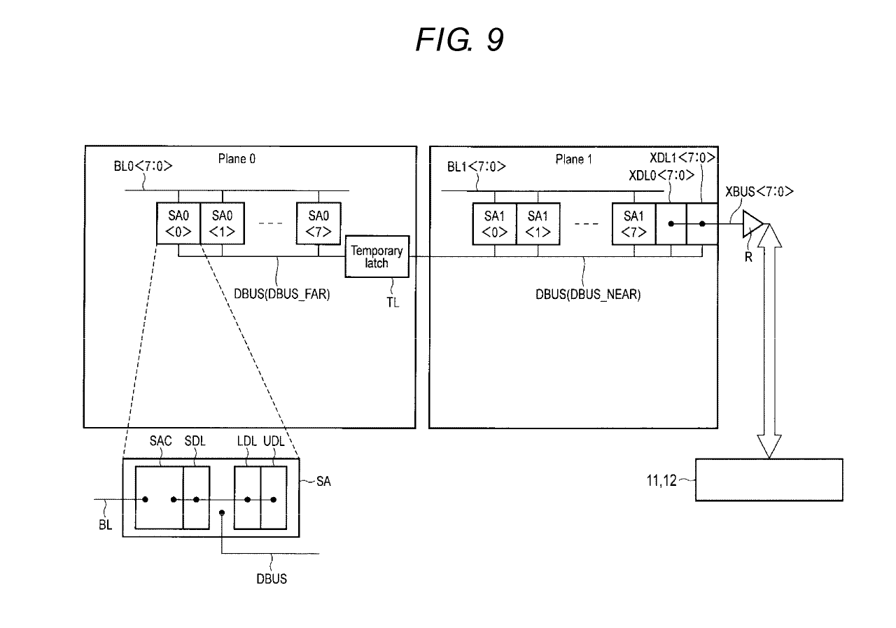

FIG. 9 shows a layout of one part of the semiconductor memory device according to the second embodiment without expressing the mutual positional relationships of each element (the components, the wirings, the circuits, and the like) in the direction along the z-axis. As shown in FIG. 9, the semiconductor memory device 1 according to the second embodiment possesses the configuration of the first embodiment (FIG. 6) as the base and further includes a temporary latch TL. The temporary latch TL is inserted in the data bus DBUS of the first embodiment and temporarily retains data on the data bus DBUS. The part of the data DBUS that that extends in the direction of the plane 0 side of the temporary latch TL, and a part of the data bus DBUS extending toward the plane 1 side of the temporary latch TL are called a DBUS_FAR and a DBUS_NEAR, respectively. The temporary latch TL is formed from, for example, the transistor Tr, the wire layers M0 and M1, the plugs CS and V1, and the like. The temporary latch TL is portrayed to be in a region in the plane 0 but may be located in the plane 1 as well. Regarding the other characteristics of the second embodiment, the descriptions of the first embodiment apply.

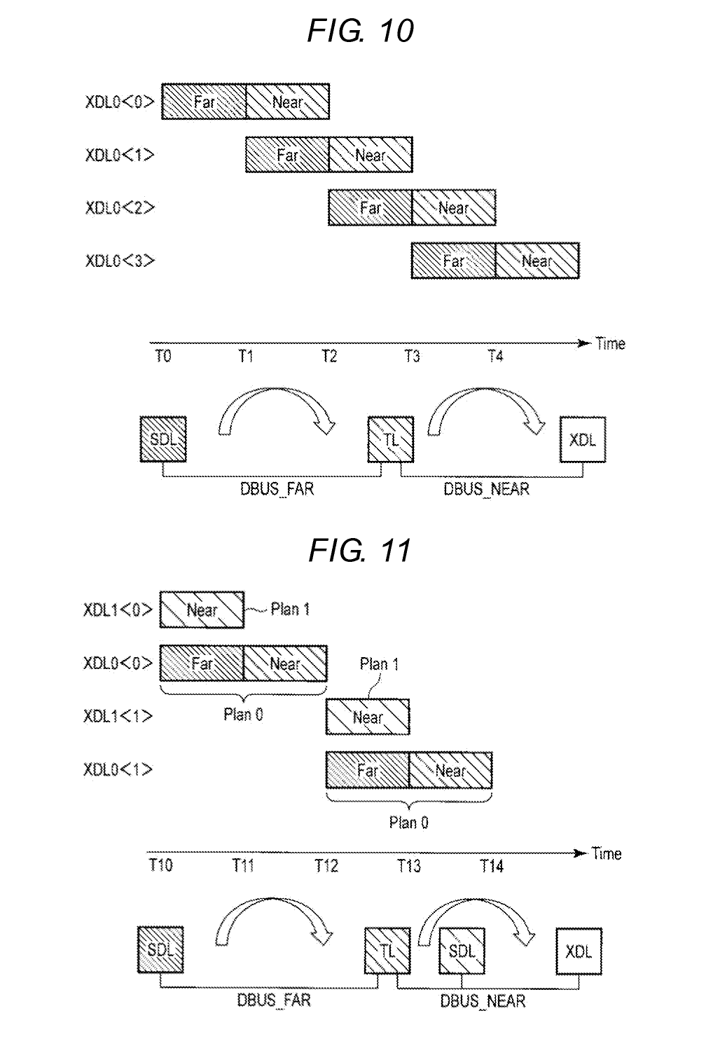

FIGS. 10 and 11 show examples of data transfer according to the second embodiment. FIG. 10 shows intensive data transfer from the far plane 0 to the latch XDL (XDL0<7:0>). FIG. 11 shows data transfer from the planes 0 and 1 to the parallel latches XDL (XDL0<7:0> and XDL1<7:0>). Latches SDL0<0> to SDL0<7> are each included in the sense amplifier units SA0<0> to SAS0<7>, and latches SDL1<0> to SDL1<7> are each included in the sense amplifier units SA1<0> to SA1<7>. The latch SDL is considered as already retaining data from the corresponding sense amplifier unit SA.

In the upper columns of FIGS. 10 and 11, data transfer from the latch SDL to the latch TL via the data bus DBUS_FAR is expressed by a block that includes the description “Far” inside. Also, data transfer from the latch TL to the latch XDL via the data bus DBUS_NEAR is expressed by a block that includes the description “Near” inside. In the upper columns of FIGS. 10 and 11, rows that entail the description XDL0<0> to XDL0<7> show the data transfer that originates at the latches SDL0<0> to SDL0<7>, which correspond to the corresponding latches XDL0<0> to XDL0<7>. Also, rows that entail the descriptions XDL1<0> to XDL1<7> show the data transfer that originates at the latches SDL1<0> to SDL1<7>, which correspond to the corresponding latches XDL1<0> to XDL1<7>. The lower columns of FIGS. 10 and 11 each collectively illustrate the latches SDL, TL, and XDL, and the hatching of these elements and the hatching of the block that shows the data transfer that originates in the corresponding element in the upper columns match.

As shown in FIG. 10, between time T0 and T1, data are transferred from the latch SDL0<0> to the latch TL. Next, between time T1 and T2, data from the latch SDL0<0> are transferred from the latch TL to the latch XDL0<0>. Also, between the time T1 and T2, data are transferred from the latch SDL0<1> to the latch TL. Similarly, between time T2 and T3, data from the latch SDL0<1> are transferred from the latch TL to the latch XDL0<1>, and data are transferred from the latch SDL0<2> to the latch TL. The process continues to proceed accordingly. In this way, parallel with data from one latch SDL being transferred from the latch TL to the latch XDL via the data bus DBUS_NEAR, data are transferred from a different latch SDL to the latch TL via the data bus DBUS_FAR. With this kind of interleave, compared to cases where the data does not go through the latch TL, part of the data transfer from the latch SDL in the far plane 0 to the XDL can be shielded, and data transfer can be sped up. Also, by inserting the latch TL in the data bus DBUS, the load on the data bus DBUS can be alleviated.

As shown in FIG. 11, between time T10 and T11, data are transferred from the latch SDL1<0> to the latch XDL1<0>. Also, between the time T10 and T11, data are transferred from the latch SDL0<0> to the latch TL. Next, between time T11 and T12, data from the latch SDL0<0> are transferred from the latch TL to the latch XDL0<0>. Between time T12 and T13, data are transferred from the latch SDL1<1> to the latch XDL1<1>. Also, between the time T12 and T13, data are transferred from the latch SDL0<1> to the latch TL. Next, between time T13 and T14, data from the latch SDL0<1> are transferred from the latch TL to the latch XDL0<1>. The process continues to proceed accordingly. In this way, parallel with data from the latch SDL in the plane 1 being transferred from the latch SDL to the latch XDL via the data bus DBUS_NEAR, data are transferred from the latch SDL in the plane 0 to the latch TL via the data bus DBUS_FAR. That is, on different planes, data are transferred in parallel via the data buses DBUS_NEAR and DBUS_FAR. With this kind of interleave, compared to cases where the data does not go through the latch TL, part of the data transfer from the latch SDL in the far plane 0 to the XDL can be shielded, and data transfer can be sped up. Also, by inserting the latch TL in the data bus DBUS, the load on the data bus DBUS can be alleviated.

The order of data transfer is not limited to this example. For example, the order does not have to be an ascending order of the latches SDL<0> to SDL<7> but can be any order.

According to the semiconductor memory device according to the second embodiment, like with the first embodiment, the data bus DBUS is shared by the multiple planes, the latches XDL for each of the planes that are connected to the data bus DBUS are collected in one location in one plane, and the data bus XBUS is also shared by the multiple planes. For this reason, the same benefits as those in the first embodiment can be obtained. Furthermore, according to the second embodiment, the latch TL is installed in the data bus DBUS. With the interleaving of the data transfer using the latch TL, part of the data transfer is shielded, and the operation of the semiconductor memory device 1 is sped up.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first sense amplifier that is positioned in a first region and amplifies signals from a memory cell in the first region;
a second sense amplifier that is positioned in a second region and amplifies signals from a memory cell in the second region;
a bus that is connected to the first and second sense amplifiers and passes through the first and second regions;
a first latch that is positioned in the second region and is connected to the bus, and
a second latch that is positioned in the second region and is connected to the bus.

2. The semiconductor memory device according to claim 1, further comprising:
a second bus that transfers signals between the first and second latches and a pad of the semiconductor memory device.

3. The semiconductor memory device according to claim 2, wherein the bus includes a first bus and a second bus, and the semiconductor memory device further comprises:
a third latch that is connected to the first sense amplifier through the first bus and is connected to the second sense amplifier through the second bus.

4. The semiconductor memory device according to claim 3, further comprising:
a control circuit that conducts data transfer from the first sense amplifier to the third latch via the first bus and data transfer from the third latch to the first latch via the second bus or data transfer from the second sense amplifier to the second latch in parallel.

5. The semiconductor memory device of claim 4, wherein
the first and second sense amplifiers and the bus are positioned between the memory cell and a substrate.

6. A semiconductor memory device comprising:
a plurality of memory cells including a plurality of planes therein;
a data bus extending in communication with at least two of the plurality of planes; and
within the at least two of the plurality of planes, a plurality of bit lines and a plurality of sense amplifiers, each bit line selectively connectable to the plurality of sense amplifiers at a first side thereof, wherein the second side of the sense amplifiers is connected to the data bus extending in communication with at least two of the plurality of planes.

7. The semiconductor memory device of claim 6, wherein a sense amplifier includes a sense amplifying circuit.

8. The semiconductor memory device of claim 7, wherein the sense amplifier includes at least one latch operatively connected thereto and intermediate of the sense amplifying circuit and the data bus.

9. The semiconductor memory of claim 6, wherein
a first plane and a second plane are positioned such that an I/O interface is accessible from a side of each plane;
each of the first and second planes include a plurality of sense amplifiers 0 to n interconnected with a plurality of bit lines 0 to n, where n is a whole number; and
the nth sense amplifier of the plurality of sense amplifiers of the first plane is located adjacent to the first plane located adjacent to the second plane, and the nth sense amplifier of the plurality of sense amplifiers of the second plane is located adjacent to the second plane located adjacent to the first plane.

10. The semiconductor memory of claim 9, further including a receiver located between the first and second planes.

11. The semiconductor memory of claim 9, further including a first receiver on a portion of the data bus extending from the first plane and a second receiver on a portion of the data bus extending from the second plane.

12. The semiconductor memory device of claim 6, wherein the data bus extends from a 0 plane through an nth plane, where n is a whole number.

13. The semiconductor device of claim 12, further including a receiver interconnected with the data bus on, or adjacent to, the nth plane.

14. The semiconductor memory device of claim 6, further including a temporary latch disposed in series communication with the data bus.

15. The semiconductor device of claim 14, wherein the temporary latch is disposed in a plane.

16. A method of configuring a semiconductor memory device, comprising:
providing a first plane of the memory including a plurality of bit lines interconnected with a plurality of sense amplifiers;
providing a second plane of the memory including a plurality of bit lines interconnected with a plurality of sense amplifiers;
providing a data bus configured to interconnect to the first plane and the second plane.

17. The method of claim 16, further including the step of providing a receiver intermediate of the first plane and the second plane.

18. The method of claim 16, further including the steps of providing a first receiver intermediate of the first plane and the interface, and a second receiver intermediate of the second plane and the interface.

19. The method of claim 16, further including the steps of:
extending the data bus through the first and the second pages; and
providing a latch at the terminus of the data bus.

20. The method of claim 19, further including the step of interconnecting the latch to the interface.
